(19) United States
(12) Patent Application Publication
(10) Pub. No.: US 2004/0016871 A1
(43) Pub. Date: Jan. 29, 2004

(54) Image pickup device

(75) Inventors: Makoto Mogamiya, Tokyo (JP); Teruo Sakai, Saitama (JP)

Correspondence Address: GREENBLUM & BERNSTEIN, P.L.C., 1950 ROLAND CLARKE PLACE, RESTON, VA, 20191, US

(73) Assignee: PENTAX Corporation, Tokyo (JP)

(21) Appl. No.: 10/619,429

(22) Filed: Jul. 16, 2003

(30) Foreign Application Priority Data
Jul. 23, 2002 (JP) 2002-213907

(51) Int. Cl. H01L 27/00

(52) U.S. Cl. 250/208.1

(57) ABSTRACT

An image pickup device includes a ceramic package in which the image pickup device is mounted, and an optical member which seals a space defined between an image pickup surface of the image pickup device and the optical member within the ceramic package. The optical member is provided, on the surface thereof which is opposed to the image pickup surface, with a coating layer formed by ion-plating, the coating layer being adhered to the ceramic package by an adhesive.

### BACKGROUND OF THE INVENTION

1. Field of the Invention

The present invention relates to an image pickup device which is mounted in a ceramic package, an image pickup surface thereof being sealed in an opening space of the ceramic package, and to a coating frame which is used to coat an optical component of an image pickup device.

2. Description of the Related Art

An image pickup device, such as a CCD, used in a digital camera, or the like, is mounted in a ceramic package and is sealed in a space which is open toward an image pickup surface. In such a ceramic package for an image pickup unit, an optical low-pass filter and an infrared absorption filter are adhered on the side which is closer to the object (via which an object image is picked up) than the image pickup surface.

An optical component, and in particular, an infrared absorption filter or a color correction filter includes different elements added thereto to obtain infrared absorbing properties or color properties. If the elements are oxidized or react with moisture (water), the oxidized or reacted portion tends to readily separate from the surface. In an optical low-pass filter or a protection glass, reaction with moisture produces burning of the surface, resulting in easy separation of the burnt portion from the remaining surface. A light path in the ceramic package is filled with nitrogen gas. If leakage of the nitrogen gas occurs at the separated surface portion, the image pickup device can deteriorate due to the leaked gas.

### SUMMARY OF THE INVENTION

The present invention eliminates the drawbacks of the prior art discussed above by enhancing the adhering and sealing efficiency of the optical components and the ceramic package.

According to an aspect of the present invention, an image pickup device is provided, including a ceramic package in which the image pickup device is mounted; and an optical member which seals a space defined between an image pickup surface of the image pickup device and the optical member within the ceramic package. The optical member is provided, on the surface thereof which is opposed to the image pickup surface, with a coating layer formed by ion-plating, the coating layer being adhered to the ceramic package by an adhesive.

The coating layer formed by the ion-plating can be made of a single layer or a plurality of layers.

The coating layer formed by the ion-plating can be made of a single layer of SiO₂, Al₂O₃, ZrO₂ or Ta₂O₅. Alternatively, the coating layer formed by the ion-plating can be made of a plurality of layers having a combination of SiO₂, Al₂O₃, ZrO₂ or Ta₂O₅.

It is desirable for the thickness of the coating layer to be in the range of 50 to 150 nm.

It is desirable for the coating layer to be formed in a shape of a frame around the peripheral edges of the optical member, the peripheral edges abutting against a stepped portion of the ceramic package.

The optical member can be an infrared absorption filter, an optical low-pass filter, a color correction filter or a protection glass, or a combination thereof.

According to another embodiment of the present invention, a coating frame for forming a coating layer onto an optical member is provided, the optical member used to seal a space defined between an image pickup surface of an image pickup device and the optical member, the coating frame including a frame portion which positions and holds the optical member in a predetermined position; a mask portion which is formed inside the frame portion and masks a surface of the optical member which is opposed to the image pickup surface; and a through-groove which extends through the mask portion, wherein the surface of the optical member, on which the coating layer is to be formed, is exposed via the through-groove.

The present disclosure relates to subject matter contained in Japanese Patent Application No. 2002-213907 (filed on Jul. 23, 2002) which is expressly incorporated herein by reference in its entirety.

### BRIEF DESCRIPTION OF THE DRAWINGS

The invention will be discussed below with reference to the accompanying drawings, in which:

FIG. 1 is a schematic view of light paths of main optical components in a single lens reflex camera having therein an image pickup device according to an embodiment of the present invention;

FIG. 2 is an enlarged side sectional view of an image pickup device shown in FIG. 1;

FIG. 3 is a underside view of an optical member mounted in an image pickup device shown in FIG. 1;

FIG. 4 is a sectional view of a support structure for an optical member shown in FIG. 3, which is subject to ion-plating;

FIG. 5 is a perspective view of an optical member holding frame used when an optical member shown in FIG. 3 is subject to ion-plating in the vicinity of the periphery thereof, viewed from the ion emitting side; and

FIG. 6 is a sectional view of a support structure used when an optical member is subject to electron-beam coating.

### DESCRIPTION OF THE PREFERRED EMBODIMENTS

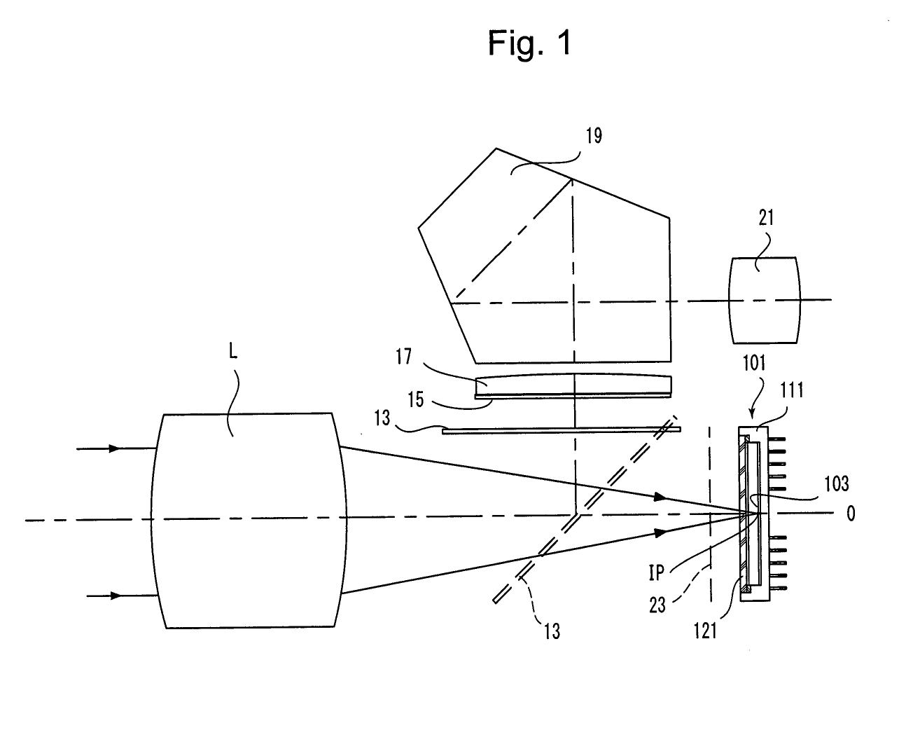

In FIG. 1 which shows the light paths of main components of a single lens reflex camera, in which an image pickup device 101 is mounted, light transmitted through a photographing lens L is reflected by a quick return mirror 13, is transmitted through a focusing screen 15 which is located at a position optically equivalent to an image forming surface position IP on design, is converged by a condenser lens 17, is reflected by a pentagonal prism 19, and is emitted from an eyepiece 21. A user can view an object image formed on the focusing screen 15, as an erect real image, through the eyepiece 21, pentagonal prism 19 and the condenser lens 17.

In order to perform a photographing operation, a focal-plane shutter curtain 23 is located slightly closer to the object than the image forming surface position IP upon design, on which the object image is formed when the quick return mirror 13 is moved up. The image pickup device 101 is arranged behind the focal-plane shutter curtain 23, with an image pickup surface 103 located at the image forming surface position IP.

Consequently, when a picture is taken, the quick return mirror 13 is moved up and the focal-plane shutter curtain 23 is opened, so that the object image is formed on the image pickup surface 103. The object image is subject to photoelectric conversion and the electric charges thus produced are accumulated (i.e., the image is picked up). The accumulated charges can be read as an electric signal after the focal-plane shutter curtain 23 is closed.

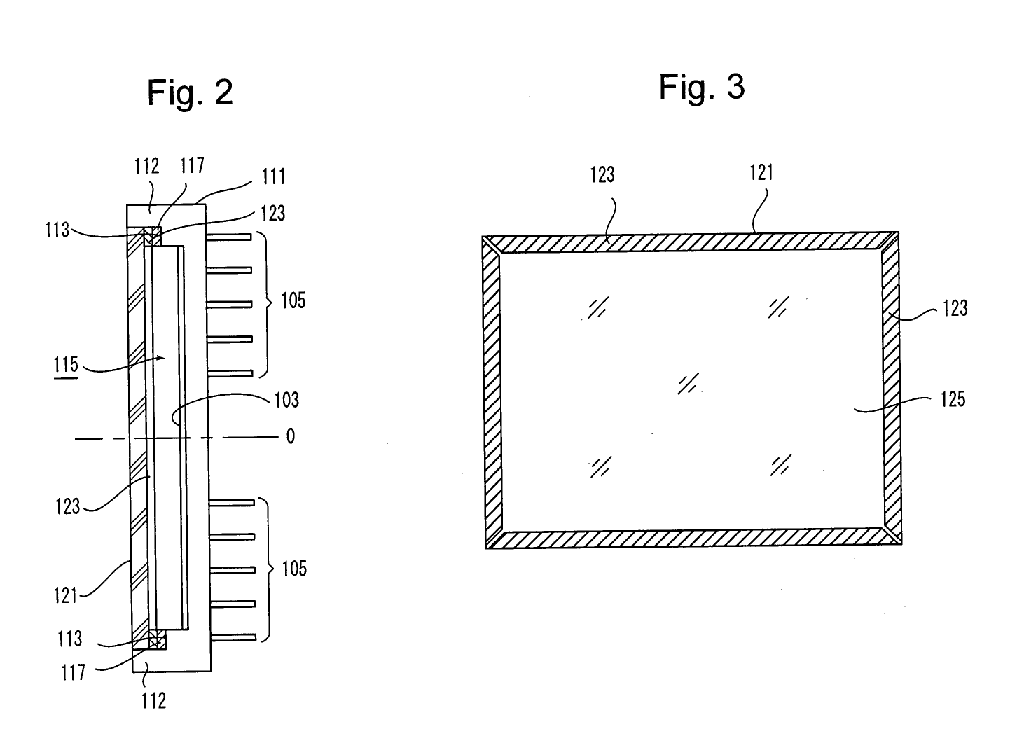

An enlarged section of the image pickup device 101 is shown in FIG. 2. The image pickup device 101 includes main components including photoelectric conversion elements, CCDs such as horizontal and vertical transfer CCDs, optical elements such as a color filter and a micro lens, and input and output pins of drive signals or image signals, etc. The main components are enclosed and sealed in a ceramic package 111.

The ceramic package 111 is in the form of a shallow box having a shallow U-shaped section. The main components of the image pickup device are mounted on the bottom of the box to form a package. The image pickup surface 103 is located at the bottom of the box.

Note that the image pickup surface 103 is defined by the color filter or micro lens that finally restricts object light incident upon the photoelectric conversion element of the main components.

An optical member 121 such as an IR (infrared) absorption filter, an optical low-pass filter, a color correction filter or a protection glass, or a combination thereof, is located in front of the image pickup surface 103 (i.e., on the object side). The optical member 121 is fitted in a stepped portion 113 formed on an inner surface of a frame 112 of the ceramic package 111 and adhered to the stepped portion 113 by an adhesive 117. The space 115 between the optical member 121 and the image pickup surface 103 is sealed and filled with nitrogen gas, which is an inert gas.

The optical member 121 is provided with a coating layer 123 formed by ion-plating (see FIG. 3), on the surface thereof to be adhered to the stepped portion 113 (i.e., the surface of the optical member adjacent to the image pickup surface 103),. The coating layer 123 can be made of a single layer of SiO₂ (silicon oxide), Al₂O₃ (aluminum oxide), ZrO₂ (zirconium oxide), or Ta₂O₅ (tantalum pentoxide), or of a plurality of layers having a combination thereof.

In the case that the coating layer 123 is made of a single layer, the substance is desirably SiO₂ or Ta₂O₅ and the next desirable substance is Al₂O₃ or ZrO₂. In the case that the coating layer 123 is made of a plurality of layers, a layer of SiO₂ and a layer of Ta₂O₅ are alternately laminated. The laminating order of the plurality of layers is determined depending on the affinity with the optical adhesive.

The thickness of the coating layer 123 is desirably in the range of 50 to 150 nm. If the coating layer 123 is thinner than 50 nm, the adhesion is insufficient and it is difficult to control the layer thickness. If the thickness of the coating layer 123 is larger than 150 nm, the stress produced in the coating layer 123 is increased, thus resulting in a possibility of deformation of the substrate (optical member 121).

In the illustrated embodiment, the coating layer 123 of the optical member 121 and the stepped portion 113 are adhered to each other by the adhesive 117 such as an optical adhesive.

The coating layer 123 formed by ion-plating is firmly secured to the material of the optical member 121 due to evaporation and is little influenced by a change in temperature or humidity. Therefore, there is no chance of the coating layer 123 becoming separated from the optical member 121.

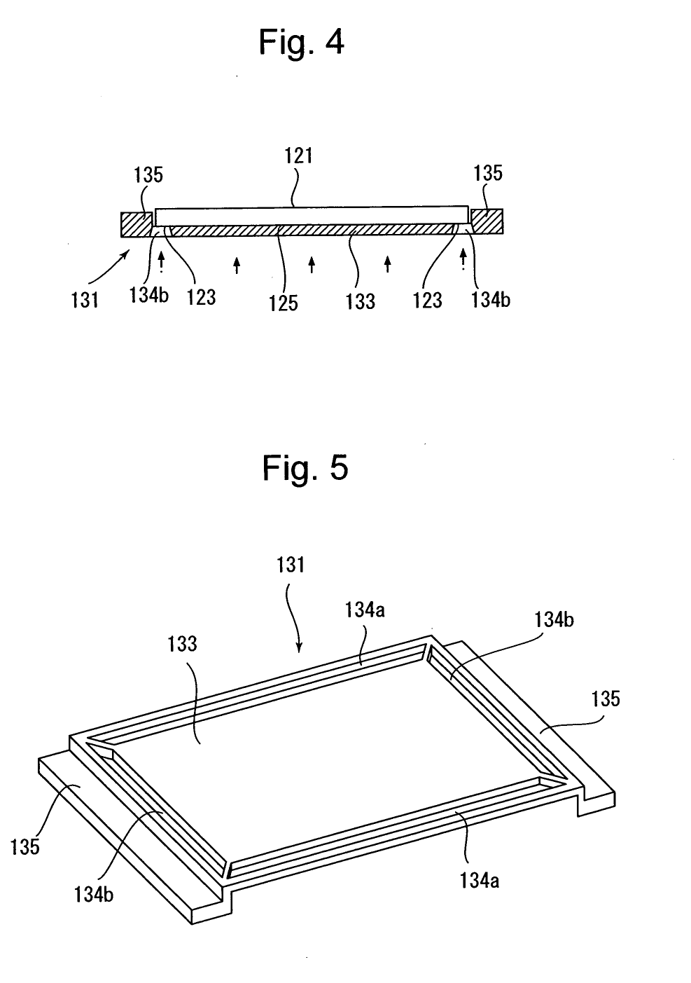

The structure of a first mask frame (coating frame) 131 which is used to form the coating layer 123 on the optical member 121 by ion-plating will be discussed below with reference to FIGS. 4 and 5. The first mask frame 131 includes a mask plate (mask portion) 133, on which the optical member 121 is placed, and a receiving frame (frame portion) 135, which extends upright from the minor side edges of the mask plate 133 and which functions also as a positioning device for the optical member 121. The mask plate 133 is substantially analogous to, and slightly larger than, the outer shape of the optical member 121. The mask plate 133 is provided with through-grooves 134a and 134b in the vicinity of the major side edges and minor side edges thereof corresponding to the coating layer 123.

The first mask frame 131 on which the optical member 121 is placed is received in an ion-plating device (vacuum tank) in which an ion of a predetermined substance is evaporated from the mask plate 133 side. The ions passing through the through-grooves 134a and 134b are applied to the optical member 121 so that the coating layer 123 is formed in the thickness direction along the through-grooves 134a and 134b. If the coating layer 123 is made of a single layer, the ion plating process continues until the thickness of the coating layer becomes 50 to 150 nm. If the coating layer is made of a plurality of layers, the ion plating of a first substance is discontinued when the thickness of the first layer of the first substance becomes a predetermined value, and thereafter, the ion plating of a second substance (second layer) is carried out. The ion plating operations are repeated until a predetermined number of layers are formed. It is desirable that the total thickness of the plural layers be in the range of 50 to 150 nm.

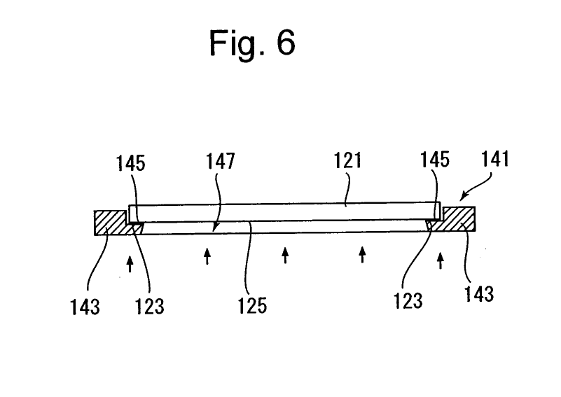

In the illustrated embodiment, after the coating layer 123 is formed, the transparent portion 125 of the optical member 121 on which the coating layer is not formed is subject to an electron-beam coating. The support structure for the electron-beam coating is shown in FIG. 6. A second mask frame 141 is provided with a frame portion 143 which surrounds the periphery of the optical member 121 and a stepped portion 145 on which the optical member 121 is placed in the frame portion 145. The stepped portion 143 substantially corresponds to the coating layer 123 of the optical member 121, so that the entire surface of the coating layer 123 comes into surface contact with the stepped portion 145, i.e., the entire surface of the coating layer is masked by the stepped portion. In other words, the transparent portion 125 which is surrounded by the coating layer 123 is exposed. The optical member 121 placed on the second mask frame 141 is received in a tank of an electron-beam coating device, so that an anti-reflection layer is formed on the transparent portion 125 surrounded by the coating layer 123, by the electron-beam coating. The anti-reflection layer can be made of a combination of SiO₂ and Ta₂O₃ or laminated layers of Al₂O₃, ZrO₂ and SiO₂. The anti-reflection layer is also provided on the opposed side of the optical member 121.

Upon assembly of the image pick up device 101, the adhesive 117 is first applied to the coating layer 123 and the stepped portion 113. Thereafter, the optical member 121, which is provided on one side thereof with the coating layer 123 formed by the ion-plate coating and the coating formed by the electron-beam coating, is adhered to the stepped portion 113 of the ceramic package 111 (via the adhesive 117) in a tank filled with nitrogen gas, and the adhesive 117 is hardened thereby to secure the image pickup device 101 in an air-tight fashion. Accordingly, as mentioned above, the space 115 between the optical member 121 and the image pickup surface 103 is sealed and filled with nitrogen gas.

In the embodiment discussed above and illustrated in the drawings, as the optical member 121 is subject to the ion-plate coating to form the coating layer 123 on the surface to be adhered to the stepped portion 113, the coating layer 123 and the stepped portion 113 tend not to separate from the adhesive 117, thus resulting in an increase in durability, and hence, there is no chance of the nitrogen gas leaking.

Although the optical member 121 is used as a member to be brought into direct contact with the nitrogen gas and to be directly adhered to the ceramic package 111 in the above-illustrated embodiments, the present invention is not limited thereto.

As can be understood from the above discussion, the optical member 121 which seals, together with the ceramic package 111, the space 115 between the image pickup surface 103 of the image pickup device 101 to be packed in the ceramic package and the optical member is adhered to the ceramic package 111 through the coating layer formed on the surface opposed to the image pickup surface by the ion-plating. Therefore, the coating layer is less influenced by humidity or temperature change, and hence, there is no chance of separation of the coating layer from the optical member, leading to a failure of sealing.

Obvious changes may be made in the specific embodiments of the present invention described herein, such modifications being within the spirit and scope of the invention claimed. It is indicated that all matter contained herein is illustrative and does not limit the scope of the present invention.

What is claimed is:

1. An image pickup device comprising:
a ceramic package in which said image pickup device is mounted; and
an optical member which seals a space defined between an image pickup surface of said image pickup device and the optical member within the ceramic package;
wherein said optical member is provided, on the surface thereof which is opposed to said image pickup surface, with a coating layer formed by ion-plating, said coating layer being adhered to the ceramic package by an adhesive.

2. The image pickup device according to claim 1, wherein the coating layer formed by the ion-plating is made of a single layer.

3. The image pickup device according to claim 1, wherein the coating layer formed by the ion-plating is made of a plurality of layers.

4. The image pickup device according to claim 1, wherein the coating layer formed by the ion-plating is made of a single layer of one of SiO₂, Al₂O₃, ZrO₂ and Ta₂O₅.

5. The image pickup device according to claim 1, wherein the coating layer formed by the ion-plating is made of a plurality of layers having a combination of any of SiO₂, Al₂O₃, ZrO₂ and Ta₂O₅.

6. The image pickup device according to claim 1, wherein the thickness of the coating layer is in the range of 50 to 150 nm.

7. The image pickup device according to claim 1, wherein the coating layer is formed in a shape of a frame around the peripheral edges of the optical member, said peripheral edges abutting against a stepped portion of the ceramic package.

8. The image pickup device according to claim 1, wherein the optical member comprises one of an infrared absorption filter, an optical low-pass filter, a color correction filter and a protection glass.

9. The image pickup device according to claim 1, wherein the optical member comprises a combination of any of an infrared absorption filter, an optical low-pass filter, a color correction filter and a protection glass.

10. A coating frame for forming a coating layer onto an optical member, said optical member used to seal a space defined between an image pickup surface of an image pickup device and the optical member, said coating frame comprising:
a frame portion which positions and holds said optical member in a predetermined position;
a mask portion which is formed inside said frame portion and masks a surface of said optical member which is opposed to said image pickup surface; and
a through-groove which extends through said mask portion, wherein said surface of said optical member, on which said coating layer is to be formed, is exposed via said through-groove.
